(19) United States
(12) Patent Application Publication
(10) Pub. No.: US 2025/0391492 A1
(43) Pub. Date: Dec. 25, 2025

(54) MEMORY DEVICE AND TESTING METHOD FOR MEMORY DEVICE

(71) Applicant: SAMSUNG ELECTRONICS CO., LTD., SUWON-SI (KR)

(72) Inventors: BYOUNGSUL KIM, SUWON-SI (KR); YOUNGSAN KANG, SUWON-SI (KR); JUNHO JUNG, SUWON-SI (KR)

(21) Appl. No.: 19/013,624

(22) Filed: Jan. 8, 2025

(30) Foreign Application Priority Data
Jun. 19, 2024 (KR) 10-2024-0079735

(51) Int. Cl. G11C 29/56

(52) U.S. Cl. CPC G11C 29/56016; G11C 29/56012; G11C 2029/5602

(57) ABSTRACT

A memory device includes a plurality of mode registers storing a plurality of status codes; a data input/output circuit that receives one status code of the plurality of status codes from one of the plurality of mode registers and samples the one status code to generate sampled data and transmit the sampled data to the serializer; and a serializer that receives the sampled data from the data input/output circuit, converts the sampled data into serial data, and outputs the serial data through a first connection terminal separate from a data connection terminal configured to exchange access data.

### CROSS-REFERENCE TO RELATED APPLICATION

This patent application claims priority under 35 U.S.C. § 119 to Korean Patent Application No. 10-2024-0079735 filed in the Korean Intellectual Property Office on Jun. 19, 2024, the disclosure of which is incorporated by reference in its entirety herein.

### (a) TECHNICAL FIELD

The present disclosure is directed to a memory device and a test method for the memory device.

### (b) DISCUSSION OF RELATED ART

Memory devices may be categorized into volatile memory, which loses stored data when the power supply is disconnected, and non-volatile, which retains stored data even when the power supply is removed. Volatile memory includes a dynamic RAM (DRAM) and a static RAM (SRAM), and non-volatile memory includes NAND flash memory and NOR flash memory.

A test device may receive signals from the memory device's input/output pins to verify its proper operation. However, attaching the test device to high-speed data pins can introduce additional loading and potential signal degradation, which may narrow the eye margin. This is especially challenging in high-speed memory devices like Universal Flash Storage (UFS) 4.0, where even small disruptions from the test device connection can impact signal quality and make accurate testing more difficult.

### SUMMARY

An embodiment provides a memory device and a test method for the memory device to accurately verify whether the memory device operates normally.

An embodiment provides a memory device that enhances area management performance by utilizing an unused connection terminal, along with a testing method for the memory device.

An embodiment provides a memory device including a test device that receives a data signal without using a data connection terminal of the memory device, along with a testing method for the memory device.

A memory device according to an embodiment includes a plurality of mode registers storing a plurality of status codes; a data input/output circuit that receives one status code of the plurality of status codes from one of the plurality of mode registers and samples the one status code to generated sampled data and output the sampled data; and a serializer that receives the sampled data from the data input/output circuit, converts the sampled data into serial data, and outputs the serial data through a first connection terminal separate from a data connection terminal configured to exchange access data.

A storage device according to an embodiment includes a storage controller that receives a monitoring enable control signal through a first connection terminal separate from a data connection terminal configured to exchange access data, serializes power status information of the storage device and gear speed information of the storage device based on the monitoring enable control signal to generate serial data, and outputs the serial data through a second connection terminal separate from the first connection terminal and the data connection terminal; and a non-volatile memory device that performs access operations based on the access data under control from the storage controller.

A test method of a memory device according to an embodiment includes reading a status code stored in one mode register among a plurality of mode registers; receiving a monitoring enable control signal through a first connection terminal separate from data connection terminal configured to exchange access data; converting the one status code into serial data based on the monitoring enable control signal; and outputting the serial data through a second connection terminal separate from the first connection terminal and the data connection terminal.

### BRIEF DESCRIPTION OF THE DRAWINGS

FIG. 1 is a block diagram showing a test system according to an embodiment.

FIG. 2 is a cross-sectional view of a memory device according to an embodiment.

FIG. 3 is a block diagram of a memory device according to an embodiment.

FIG. 4 is a block diagram of a memory device according to an embodiment.

FIG. 5 is a flowchart showing a process of a serial data being output through a second connection terminal.

FIG. 6 is an example of a data stored in a mode register.

FIG. 7 is a view showing an example of a serial data being output based on a monitoring enable signal.

FIG. 8 is a block diagram showing a test system according to an embodiment.

FIG. 9 is a cross-sectional view of a storage device according to an embodiment.

FIG. 10 is an example diagram of a data sampling ratio and a data storage time according to a capacity of a non-volatile memory device.

FIG. 11 is an example diagram showing a power status information and a gear speed information that are changed when a storage device receives a command from a test device.

FIG. 12 is a block diagram of a storage controller according to an embodiment.

FIG. 13 is a block diagram showing an example of a non-volatile memory device included in a storage device according to an embodiment.

FIG. 14 is a flowchart showing a process of a serial data being output through a second connection terminal.

FIG. 15 is an example diagram of a power status information and a gear speed information stored in a firmware.

FIG. 16 is an example diagram of a serial data being output based on a monitoring enable signal.

FIG. 17 is a block diagram showing a computing system including a non-volatile memory device according to an embodiment.

### DETAILED DESCRIPTION

In the following detailed description, only certain embodiments of the present disclosure have been shown and described, simply by way of illustration. As those skilled in the art would realize, the described embodiments may be modified in various different ways, all without departing from the spirit or scope of the present disclosure.

Accordingly, the drawings and description are to be regarded as illustrative in nature and not restrictive. Like reference numerals designate like elements throughout the specification. In a flowchart described with reference to the drawings, an order of operations may be changed, several operations may be merged, some operations may be divided, and specific operations may not be performed.

In addition, expressions written in the singular may be construed in the singular or plural unless an explicit expression such as “one” or “single” is used. Terms including ordinal numbers such as first, second, and the like will be used only to describe various components, and are not to be interpreted as limiting these components. These terms may be used for the purpose of distinguishing one constituent element from other constituent elements.

Hereinafter, the present disclosure will be explained in more detail through an example. These examples are merely intended to illustrate embodiments of the present disclosure, but the present disclosure is not limited by these examples.

The inventive concept addresses the issues encountered when connecting a test device to a data connection terminal (e.g., for exchanging access data) of a memory device by leveraging unused access terminals within the device memory, incorporating a serializer, and reducing the output data speed in the test environment using a test device such as a probe. This approach allows for effective verification of the data signal's integrity.

The serializer may initiate an operation upon receiving a monitoring enable control signal from a first one of the unused access terminals. It may receive sampled status codes from data I/O circuitry, as well as an internal clock signal from clock control circuitry. Using this internal clock, the serializer may convert the sampled codes into serial data, which is then output to the test device via a second one of the unused access terminals.

The serializer's functionality may be further enhanced as it can receive power state information or gear speed information stored in firmware. Upon receiving the monitor enable control signal from host interface circuitry via the first unused access terminal, it may serialize this information based on the internal clock signal and output the generated serial data signal through the second unused access terminal.

The use of the serializer and the unused access terminals simplifies signal integrity verification by routing data to the test device in a manageable format, ultimately overcoming the challenges posed by high-speed direct connections to data pins.

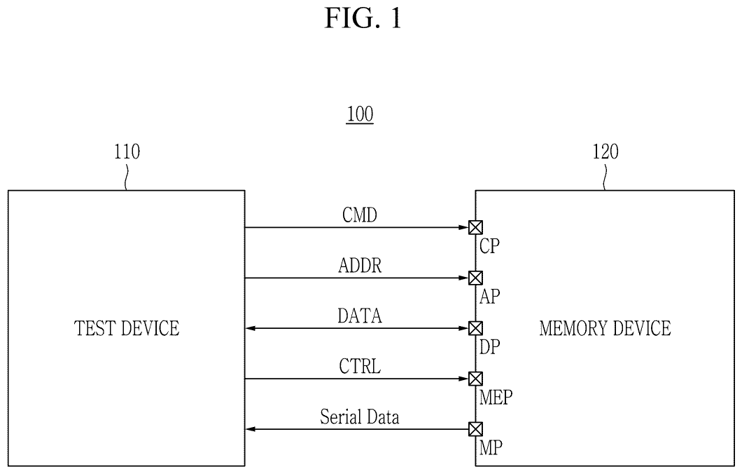

FIG. 1 is a block diagram showing a test system according to an embodiment.

Referring to FIG. 1, a test system 100 includes a test device 110 (e.g., a probe) and a memory device 120. The memory device 120 may receive a command CMD, an address ADDR, a data signal DATA, and a control signal CTRL from the test device 110, respectively, through a command connection terminal CP, an address connection terminal AP, a data connection terminal DP, and a first connection terminal MEP. The data connection terminal DP may be for exchanging access data (e.g., outputting read data read from the memory device 120 or receiving write data to write to the memory device 120).

The test device 110 may provide the command signal CMD and the address signal ADDR to the memory device 120 to access a memory cell array of the memory device 120 and control memory operations such as reading or writing. The data signal DATA may be transmitted from the memory device 120 to the test device 110 according to the read operation, and the data signal DATA may be transmitted from the test device 110 to the memory device 120 according to the write operation.

In some embodiments, the test device 110 may transmit a write command signal CMD, an address signal ADDR, and a write data signal DATA to the memory device 120 to control a write operation for a plurality of cells included in the memory cell array. While the test device 110 transmits the write command signal CMD to the memory device 120, the test device 110 may transmit the data signal DATA to the memory device 120. Accordingly, a data transfer rate of the data signal DATA transmitted by the test device 110 to the memory device 120 may be higher than the data transfer rate of the command signal CMD and the address signal ADDR transmitted by the test device 110 to the memory device 120.

In some embodiments, the test device 110 may transmit a read command signal CMD and an address signal ADDR to the memory device 120 to control a read operation. While the test device 110 transmits the read command signal CMD to the memory device 120, the memory device 120 may transmit the data signal DATA to the test device 110. Accordingly, the data transfer rate of the data signal DATA transmitted from the memory device 120 to the test device 110 may be higher than the data transfer rate of the command signal CMD and the address signal ADDR transmitted from the test device 110 to the memory device 120.

Due to the high data transfer rate of the data signal DATA transmitted from the memory device 120 to the test device 110, an eye margin of the data signal DATA may become narrow. A narrow eye margin in the context of high data transfer rates means that the time window in which the data signal can be accurately read becomes smaller. In digital communications, an “eye diagram” visually represents the signal quality over time, showing the ideal moments for reading the high and low states of a signal. As the eye margin of the data signal DATA narrows during transmission from the memory device 120 to the test device 110, the data signal DATA may become distorted. With the decrease in signal strength, it may become challenging for the test device 110 to accurately recognize the data signal DATA. Consequently, the high data transfer rate of the data signal DATA may lead to errors in the operation of the test system 100.

In an embodiment, the memory device 120 receives the monitoring enable control signal CTRL from the test device 110 through the first connection terminal MEP. In an embodiment, the memory device 120 receives the monitoring enable control signal CTRL to initiate the operation of a serializer. In an embodiment, the first connection terminal MEP is not one of the data connection terminals (DP) of the memory device 120. For example, the first connection terminal MEP may be separate and distinct from the data connection terminals (DP).

In some embodiments, the memory device 120 may receive a test entry mode command signal TMRS from the test device 110. The memory device 120 may receive the test entry mode command signal TMRS to initiate the operation of a serializer.

In some embodiments, the test device 110 may receive serial data generated by the serializer within the memory device 120. The serializer can serialize the data signal DATA to generate a serial data signal and output the serial data signal to the second connection terminal (MP). In an embodiment, the second connection terminal MP is not one of the data connection terminals (DP) of the memory device 120. For example, the second connection terminal MP may be separate and distinct from the data connection terminals (DP).

While the serial data signal is transmitted sequentially one bit at a time, the data signal DATA is transmitted simultaneously with several bits, so the data transfer rate of the serial data signal Serial Data may be less than or equal to the data transfer rate of the data signal DATA. If the data transfer rate is low, the time to transmit each bit increases, and the eye margin may increase. Accordingly, the eye margin of the serial data signal Serial Data may be larger than the eye margin of the data signal DATA.

The test device 110 may receive the serial data signal Serial Data through the second connection terminal MP. The test device 110 may sample the serial data signal Serial Data.

In some embodiments, the memory device 120 may be implemented as a semiconductor package, and the semiconductor package may include a substrate and a plurality of integrated circuit (IC) elements mounted on the substrate. The semiconductor package may be implemented as a package on package (POP), a chip scale package (CSP), a die in waffle pack, a die in wafer form, a chip on board (COB), a system in package (SIP), a multi-chip package (MCP), a wafer-level fabricated package (WFP) or a wafer-level processed stack package (WSP), but is not limited thereto.

The semiconductor package may include a plurality of connection terminals and may be attached to the substrate. The connection terminal may be, for example, a solder ball or a bump. The connection terminal may electrically connect the semiconductor package to the test device 110.

In some embodiments, the memory device 120 may be implemented as an IC device. The IC device may be a memory semiconductor device or a logic semiconductor device. The memory semiconductor device may be a dynamic random access memory (DRAM). The logic semiconductor device may be a central processing unit (CPU), a graphic processing unit (GPU), a controller, an application specific integrated circuit (ASIC), or an application processor (AP).

The memory device 120 may include an IC element in a packaged form. The IC element in the packaged form may include a plurality of connection terminals such as solder balls and bumps on its surface. The IC element may also be referred to as a semiconductor chip or a semiconductor die.

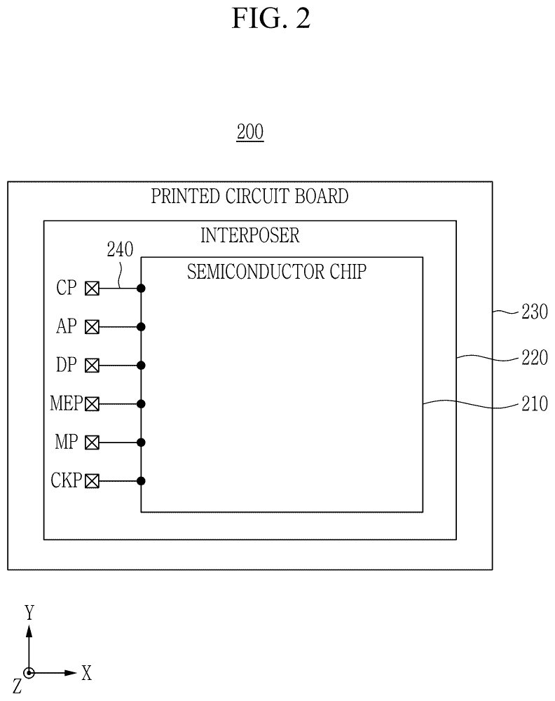

FIG. 2 is a cross-sectional view of a memory device according to an embodiment. The memory device 200 of FIG. 2 may be used to implement the memory device 120 of FIG. 1.

Referring to FIG. 2, the memory device 200 includes a semiconductor chip 210, an interposer 220 mounting the semiconductor chip 210 (e.g., a memory), and a printed circuit board (PCB) 230. The semiconductor chip 210, the interposer 220, and the printed circuit board (PCB) 230 may be arranged to overlap on a plane having an X-axis and a Y-axis. The interposer 220 may be positioned on the printed circuit board (PCB) 230 in a Z axis as a reference, and the semiconductor chip 210 may be positioned on the interposer 220.

The command connection terminal CP, the address connection terminal AP, the data connection terminal DP, a clock connection terminal CKP, the first connection terminal MEP, and the second connection terminal MP may be connected to the semiconductor chip 210 through a wiring 240. In an embodiment, the command connection terminal CP, the address connection terminal AP, the data connection terminal DP, the clock connection terminal CKP, the first connection terminal MEP, and the second connection terminal MP may be positioned on the interposer 220. In some embodiments, the command connection terminal CP, the address connection terminal AP, the data connection terminal DP, the clock connection terminal CKP, the first connection terminal MEP, and the second connection terminal MP may be positioned on the substrate 230. However, for better understanding and ease of description, it is assumed that the command connection terminal CP, the address connection terminal AP, the data connection terminal DP, the clock connection terminal CKP, the first connection terminal MEP, and the second connection terminal MP are positioned on the interposer 220.

The test device (10 of FIG. 1) may transmit the command signal CMD, the address signal ADDR, the data signal DATA, the clock signal CK, and the monitoring enable control signal CTRL to the memory device 200 through the command connection terminal CP, the address connection terminal AP, the data connection terminal DP, the clock connection terminal CKP, and the first connection terminal MEP positioned on the interposer 220, respectively.

The test device 110 may detect the serial data signal Serial Data transmitted from the memory device 200 to the test device 110 through the second connection terminal MP positioned on the interposer 220.

In some embodiments, the first connection terminal MEP and the second connection terminal MP are not added to the memory device 200. In this case, among the plurality of connection terminals included in the memory device 200, some of the terminals except the command connection terminal CP, the address connection terminal AP, the data connection terminal DP, and the clock connection terminal CKP can be used as the first connection terminal MEP or the second connection terminal MP.

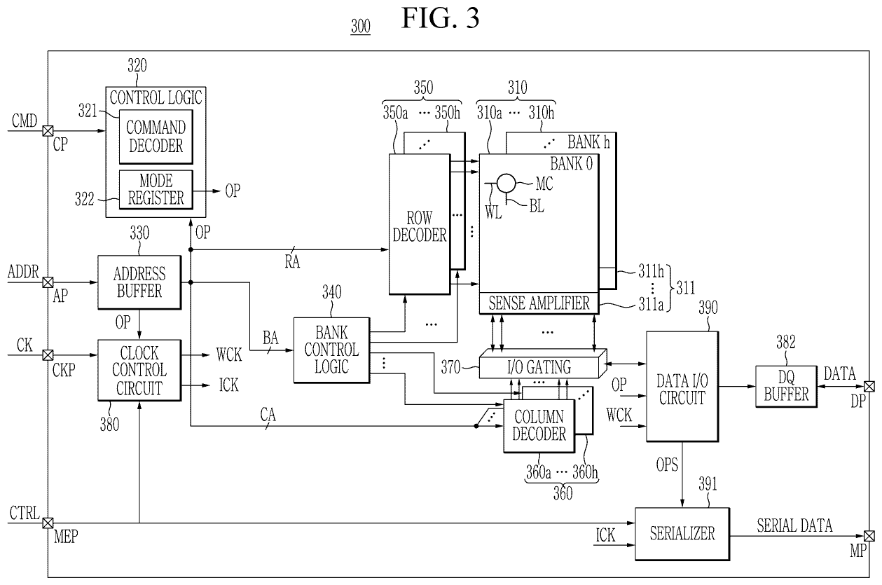

FIG. 3 is a block diagram of a memory device according to an embodiment. The memory device of FIG. 3 may be used to implement the semiconductor chip 210.

Referring to FIG. 3, a memory device 300 includes a memory cell array 310, a sensing amplifier 311, a control logic circuit 320, an address buffer 330, a row decoder 350 (e.g., a first decoder circuit), a column decoder 360 (e.g., a second decoder circuit), an input/output gating circuit 370, a clock control circuit 380, a data input/output circuit 390, and a serializer 391.

The memory cell array 310 includes a plurality of memory cells MC. In some embodiments, the memory cell array 310 may include a plurality of memory banks 310a to 310h. FIG. 3 shows eight memory banks BANK0 to BANK7, or 310a to 310h, but the number of the memory banks is not limited to this. Each memory bank 310a to 310h may include a plurality of memory cells MC arranged at a plurality of rows, a plurality of columns, and the intersection of the plurality of rows and the plurality of columns. In some embodiments, the plurality of rows may be defined by a plurality of word lines WL, and the plurality of columns may be defined by a plurality of bit lines BL.

The control logic circuit 320 may receive the command signal CMD from the test device (110 in FIG. 1) through the command connection terminal CP and control the operation of the memory device 300 based on the command signal CMD. For example, the control logic circuit 320 may generate a control signal so that the memory device 300 performs the read operation or the write operation in response to receiving the command signal CMD.

In some embodiments, the control logic circuit 320 may initiate the operation of the serializer 391 based on the monitoring enable control signal CTRL and control the clock control circuit 380 to generate an internal clock signal.

In some embodiments, the control logic circuit 320 may include a command decoder 321 (e.g., a decoder circuit). The command decoder 321 may generate a control signal by decoding the command signal CMD received from the test device 110. The command decoder 321 may decode the command signal CMD output from the test device 110 and control internal components of the memory device 300 based on a result of the decode. For example, the command decoder 321 may decode an activation command, a read command, a write command, a precharge command, a mode register write command, a mode register read command, a test entry mode command, or a multi-purpose command (MPC) from the command signal CMD. All of the above-mentioned commands may be determined in advance in a Joint Electron Device Engineering Council (JEDEC) standard.

In some embodiments, the control logic circuit 320 may further include a mode register 322 for setting the operation mode of the memory device 300. The mode register 322 may store a plurality of OP codes provided from the address buffer 330. The number of the mode registers 322, the address, the size of the OP codes, etc. may be defined in the JEDEC standard. The test device 110 may change the values stored in the mode register 322 and set the operating conditions and operation modes of the memory device 300 by issuing a mode register write command and a code. The control logic circuit 320 may receive the mode register read command signal CMD from the test device 110 and issue a command to ensure that the OP code stored in the mode register 322 is transmitted to the data input/output circuit 390. For example, the OP code may be associated with the received mode register read command signal CMD.

In some embodiments, the test device 110 may change the values stored in the mode register 322 and set the operation mode of the memory device 300 by issuing a mode register write command signal CMD and an OP code. The control logic circuit 320 may receive the mode register write command signal CMD from the test device 110 and then issue a command to transmit the OP code to be changed in the mode register 322 to the data input/output circuit 390.

In some embodiments, the test device 110 may read the values stored in the mode register 322 by issuing the mode register read command signal CMD. For example, when the test device 110 issues the mode register read command signal CMD, the memory device 300 may output the corresponding OP code stored in the mode register 322 through the data connection terminal DP. When the test device 110 issues the mode register read command signal CMD, the memory device 300 may output the corresponding OP code stored in the mode register 322 through the second connection terminal MP. In this case, the OP code serialized by the serializer 391 may be output.

There may be a plurality of mode registers 322, and each of the plurality of mode registers 322 may include an OP code corresponding to a plurality of memory banks. For example, each of the plurality of mode registers 322 may include the OP codes corresponding to eight memory banks (BANK0 to BANK7, 310a to 310h). In an embodiment, the OP code may include a power status information Power Status, a gear speed information Gear Speed, and a Post package Repair (PPR) information, corresponding to each memory bank. Since the OP code may provide status information, it may also be referred to as a status code or status data. The power status information Power Status may indicate the current power state such as whether the device is in a low-power mode, an active mode, or a standby mode. The gear speed information Gear Speed may refer to the data transfer speed setting of the memory device. The PPR information may include: information on which specific blocks or sectors of the memory are defective and have been remapped to functional spare areas; flags or status bits indicating whether post-package repairs have been performed and whether they were successful; details on the number and location of spare blocks allocated to replace defective areas; and/or a record of previous repairs, including when repairs occurred, which blocks were affected, and any issues encountered.

The address buffer 330 may receive the address signal ADDR provided from the test device 110 through the address connection terminal AP. The address signal ADDR may include a row address signal RA indicating the row of the memory cell array 310 and a column address signal CA indicating the column. The row address signal RA is provided to the row decoder 350, and the column address signal CA is provided to the column decoder 360. In some embodiments, the address signal ADDR may further include a bank address signal BA indicating a memory bank. The bank address signal BA may be provided to the bank control logic 340.

The address buffer 330 may provide the address signal ADDR received along with the mode register write command from the test device 110 to the mode register 322 and/or the clock control circuit 380 as the code OP. Here, the OP code OP may be transmitted through transmission paths of the command signal CMD and/or the address signal ADDR between the test device 110 and the memory device 300. Since the OP code OP is stored in the mode register 322, it may also be referred to as an operation code (OPCODE) or an operand.

In some embodiments, the memory device 300 may further include bank control logic 340 that generates a bank control signal in response to the bank address BA. The bank control logic 340 may respond to the bank control signal to activate the row decoder 350 corresponding to the bank address BA among the plurality of row decoders 350, and activate the column decoder 360 corresponding to the bank address BA among the plurality of column decoders 360.

The row decoder 350 selects the row to be activated among the plurality of rows in the memory cell array 310 based on the row address RA. For this purpose, the row decoder 350 may apply a driving voltage to the word line corresponding to the row to be activated. In some embodiments, a plurality of row decoders 350a to 350h may be provided, corresponding to the plurality of memory banks 310a to 310h.

The column decoder 360 selects the column to be activated among the plurality of columns in the memory cell array 310 based on the column address. To this end, the column decoder 360 may activate the sensing amplifier 311 corresponding to the column address CA through the input/output gating circuit 370. In some embodiments, a plurality of column decoders 360a to 360h corresponding to plurality of memory banks 310a to 310h, respectively, may be provided. In some embodiments, the input/output gating circuit 370 may gate input and output data, and include a data latch to store data read from the memory cell array 310, and a write driver to write data to the memory cell array 310. The data read from the memory cell array 310 may be sensed by the sensing amplifier 311 and stored in the input/output gating circuit (370, for example, a data latch). In some embodiments, a plurality of sensing amplifiers 311a to 311h corresponding to the plurality of memory banks 310a to 310h, respectively, may be provided.

In some embodiments, the data read from the memory cell array 310 (e.g., the data stored in the data latch) may be provided to the test device 110 through the data input/output circuit 390. The data to be written into the memory cell array 310 may be provided to the data input/output circuit 390 from the test device 110, and the data provided to the data input/output circuit 390 may be provided to the input/output gating circuit 370.

The clock control circuit 380 may receive the clock signal CK from the test device 110 through the clock connection terminal CKP. The clock control circuit 380 may generate an internal clock signal ICK by buffering the clock signal CK. The phase of the buffered internal clock signal ICK may be almost the same as the phase of the clock signal CK. In some embodiments, the clock control circuit 380 may generate the internal clock signal ICK by dividing the clock signal CK.

The clock control circuit 380 may generate a data clock signal WCK by delaying the clock signal CK. The clock control circuit 380 may adjust the delay of the clock signal CK by using the code OP. In an embodiment, the frequency of the data clock signal WCK is different from the internal clock signal ICK.

In some embodiments, the clock control circuit 380 may generate the internal clock signal ICK based on the monitoring enable control signal CTRL. In an embodiment, the clock control circuit 380 receives the monitoring enable control signal CTRL through the first connection terminal MEP and generates the internal clock signal ICK in response to the monitoring enable control signal CTRL.

The DQ buffer 382 may receive the data signal DATA from the test device 110 or output the data signal DATA to the test device 110. Since the data signal DATA is a bi-directional signal, the DQ buffer 382 may include a receiver that receives the data signal DATA and a transmitter that outputs the data signal DATA.

The data input/output circuit 390 may receive the data clock signal WCK from the clock control circuit 380 and the OP code OP from the mode register 322. The data input/output circuit 390 may sample the OP code OP in synchronization with the data clock signal WCK. The data input/output circuit 390 may output the OP code OP to the test device 110 through the data connection terminal DP. Additionally, the data input/output circuit 390 may transmit the sampled OP code OPS to the serializer 391.

The serializer 391 may receive the monitoring enable control signal CTRL from the test device 110 through the first connection terminal MEP, and initiate the operation of the serializer 371 in response to receipt of the monitoring enable control signal CTRL. The serializer 391 may receive the internal clock signal ICK from the clock control circuit 380, and convert the sampled OP code OPS received from the data input/output circuit 390 into a serial data signal Serial Data based on the internal clock signal ICK. The serializer 391 may transmit the serial data signal Serial Data to the test device 110 through the second connection terminal MP.

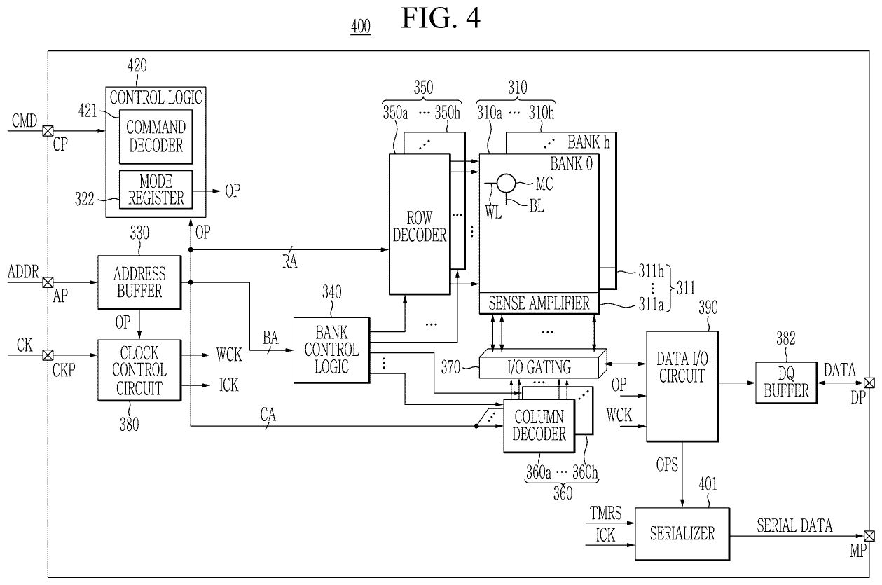

FIG. 4 is a block diagram of a memory device according to an embodiment. The memory device of FIG. 4 may be used to implement the semiconductor chip 210.

The description of components that are identical or similar between the memory device 400 in FIG. 4 and the memory device 300 in FIG. 3 is omitted. The focus of the description for memory device 400 in FIG. 4 is primarily on the differences between the memory device 400 in FIG. 4 and the memory device 300 in FIG. 3.

Referring to FIG. 4, the memory device 400 may receive a test entry mode command signal TMRS, and the operation of the serializer 401 may be initiated by the test entry mode command signal TMRS. Therefore, compared with FIG. 3, the memory device 400 in FIG. 4 does not receive the monitoring enable control signal (CTRL in FIG. 3).

The control logic circuit 420 may receive the test entry mode command signal TMRS from the test device (110 in FIG. 1) through the command connection terminal CP. The control logic circuit 420 may control the operation of the memory device 400 based on the test entry mode command signal TMRS.

In some embodiments, the control logic circuit 420 may receive the test entry mode command signal TMRS from the test device 110 and initiate the operation of the serializer 401 based on the test entry mode command signal TMRS.

The command decoder 421 may generate a control signal by decoding the command signal CMD received from the test device 110. The command decoder 421 may decode the test entry mode command signal TMRS output from the test device 110 to control internal components of the memory device 400. For example, the command decoder 421 may control the operation of the serializer 401 by decoding the test entry mode command signal TMRS.

The serializer 401 may receive the test entry mode command signal TMRS from the test device 110 through the command connection terminal CP. The operation of the serializer 401 may be started immediately after the serializer 401 receives the test entry mode command signal TMRS. The serializer 401 may convert the sampled OP code OPS received from the data input/output circuit 390 into the serial data signal Serial Data based on the internal clock signal ICK. The serializer 401 may transmit the serial data Serial Data to the test device 110 through the second connection terminal (MP of FIG. 1). For example, the serializer 401 may begin converting the sampled OP code OPS after receiving the test entry mode command signal TMRS.

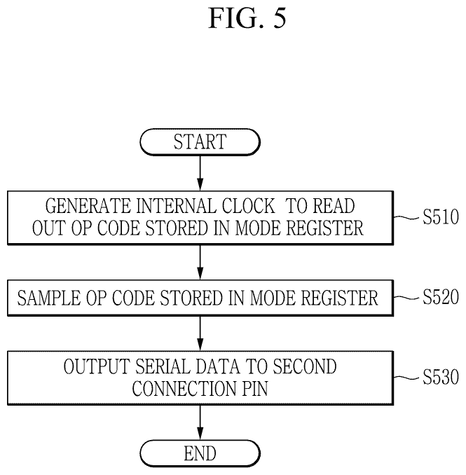

FIG. 5 is a flowchart showing a process of outputting serial data through a second connection terminal.

In a step (S510), the memory device (120 in FIG. 1) may generate the internal clock (ICK in FIG. 3, ICK in FIG. 4) to read the OP code stored in the mode register (322 in FIG. 3). In some embodiments, the memory device 120 may receive the monitoring enable signal (CTRL of FIG. 3) through the first connection terminal (MEP of FIG. 1) from the test device (110 of FIG. 1) and generate the internal clock (ICK of FIG. 3) based on the monitoring enable control signal CTRL. In some embodiments, the memory device 120 may receive the test entry mode command signal TMRS from the test device 110 and generate an internal clock (ICK in FIG. 4) based on the test entry mode command signal TMRS.

In a step (S520), the memory device 120 may sample the OP code stored in the mode register 322. The memory device 120 may generate the data clock signal (WCK in FIG. 3, WCK in FIG. 4) to sample the OP code stored in the mode register 322. The data clock signal (WCK in FIG. 3, WCK in FIG. 4) may be generated based on the clock signal CK received from the test device 110 through the clock connection terminal CKP. The memory device 120 may sample the OP code stored in the mode register 322 by using the data clock signal (WCK in FIG. 3, WCK in FIG. 4). In an embodiment, the OP code stored in the mode register 322 stores information about a power status information Power Status, a gear speed information Gear Speed, and a PPR (Post Package Repair) of the memory device 120.

In a step (S530), the memory device 120 may output the serial data to the test device 110 through the second connection terminal MP of FIG. 1. The memory device 120 may generate the internal clock signal (ICK in FIG. 3, ICK in FIG. 4) to generate the serial data Serial Data. The internal clock signal (WCK in FIG. 3, WCK in FIG. 4) may be generated based on the clock signal CK received from the test device 110 through the clock connection terminal CKP. The memory device 120 may convert the OP code OPS sampled in the step (S520) into the serial data Serial Data based on the internal clock signal ICK.

Specifically, the serializer (e.g., 401) may generate the serial data Serial Data by converting the sampled OP code OPS, which is stored in parallel, into a serial format. When the amount of the information of the serial data Serial Data is less than the amount of the information stored in the mode register 322, the data transfer rate of the serial data Serial Data may be lower than the data transfer rate of the sampled OP code OPS. The memory device 120 may output the serial data Serial Data to the test device 110 through the second connection terminal (MP of FIG. 1).

In some embodiments, the serializer may receive the monitoring enable control signal CTRL, and initiate the operation of the serializer based on the monitoring enable control signal CTRL. In some embodiments, the serializer may receive the test entry mode command signal TMRS, and the operation of the serializer may be initiated based on the test entry mode command signal TMRS.

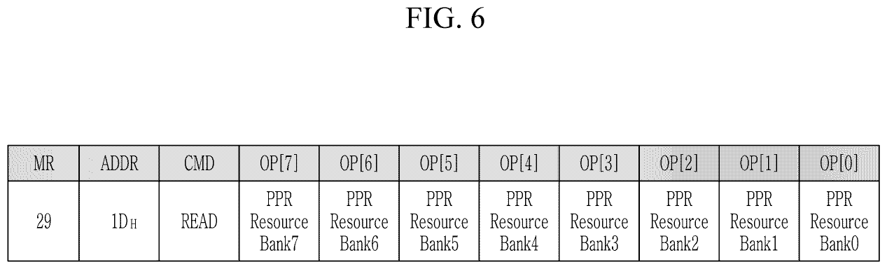

FIG. 6 is an example diagram of data stored in a mode register (e.g., 322). The mode register 322 may be one of a plurality of mode registers.

Referring to FIG. 6, data stored in each of the plurality of mode registers (322 in FIG. 3) may include information related to an address ADDR, a command CMD, and an OP code. The address indicating each mode register 322 may be specified by the address ADDR information. The mode register 322 specified by the address ADDR information may be used to perform a write or read operation based on the command CMD. Each of the plurality of banks included in mode register 322, which is the target of the write or read operation, may be specified based on the OP code.

For example, when reading information stored in the twenty-ninth mode register 322, the mode register 322 may receive a 1D_{H} address ADDR in hexadecimal from the address buffer 330 in FIG. 3 and a read command READ CMD from a command buffer. At this time, the information about the PPR for each bank may be stored in the eight OP fields included in the twenty-ninth mode register 322. The first OP field OP[0] may store the PPR information for the 1st bank, the second OP field OP[1] may store the PPR information for the 2nd bank, and the third OP field OP[2] may store the PPR information for the 3rd bank. Likewise, the OP[3], OP[4], OP[5], OP[6], and OP[7] may also the store PPR information for the corresponding bank.

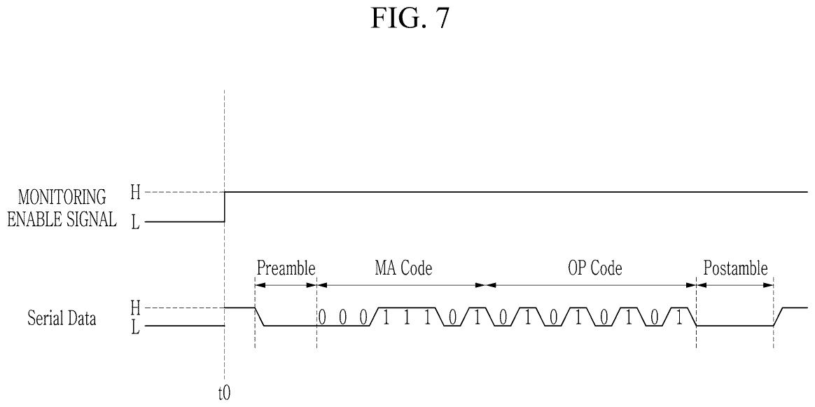

FIG. 7 is an example diagram of serial data being output based on a monitoring enable signal.

Referring to FIG. 7, the memory device (120 in FIG. 1) may receive a monitoring enable signal Monitoring Enable Signal of logic high level H at time t0 and receive a mode register read command signal CMD. In some embodiments, the memory device 120 may receive an address signal ADDR indicating a specific mode register. For example, the memory device 120 may receive the address signal ADDR indicating a twenty-ninth mode register. The memory device 120 may read the information stored in the mode register 322 after time t0, serialize the read information to generate a serial data signal Serial Data, and output the serial data signal Serial Data. For example, the memory device 120 may read the information about PPR stored in the field for bank 1, the field for bank 3, the field for bank 5, and the field for bank 7 stored in the twenty-ninth mode register, serialize this information, and output the serial data signal Serial Data.

The serial data Serial Data may include mode register address information and an OP code including the address information that specifies one mode register among the plurality of mode registers. In addition, the serial data Serial Data may be output through a section Preamble that outputs a preamble, a section MA Code that outputs a mode register address code, a section OP Code that outputs the OP code, and the section Postamble that outputs a postamble. At this time, the OP code, as explained in FIG. 6, may include the information about each of the plurality of banks included in the mode register (322 in FIG. 3).

The memory device 120 may respectively transmit the mode register address information and the OP code in the section MA Code that outputs the mode register address code and the section OP Code that outputs the OP code between the preamble section Preamble and the postamble section Postamble. In detail, the serializer (391 of FIG. 3), when the monitoring enable control signal CTRL transitions from a disable level L to an enable level H, may output the mode register address code and the OP code corresponding to one mode register among the plurality of mode registers as the serial data. Also, the serializer 391, when the monitoring enable control signal transitions from the disable level L to the enable level H, may output the preamble before the serial data and output the postamble Postamble after outputting the serial data Serial Data.

During the preamble section Preamble, the memory device 120 may perform a timing synchronization with the test device 110, so that the start of the data transmission may be clearly recognized. During the postamble section Postamble, the memory device 120 may clearly recognize the mode register address information and the end of the OP code, so the accuracy of the data processing may be increased.

The memory device 120 may transmit 8 bit data (‘00011101’) to the test device 110 during the mode register address code (MA Code) section. The 8-bit data (‘00011101’) transmitted to the test device 110 during the mode register address code MA Code section may indicate the address of the twenty-ninth mode register 322.

The memory device 120 may output one among the power status information Power Status, the gear speed information Gear Speed, and the PPR information corresponding to each of the plurality of memory banks 310a to 310h included in the memory cell array (310 in FIG. 3) during the OP code section OP Code as the OP code. For example, the memory device 120 may transmit 8 bit data (‘01010101’) to the test device 110 during the OP code section OP Code. The 8-bit data (‘01010101’) transmitted to the test device 110 during the mode register OP code section OP Code may indicate the information about the PPR of the bank 1, the bank 3, the bank 5, and the bank 7 included in the twenty-ninth mode register 322.

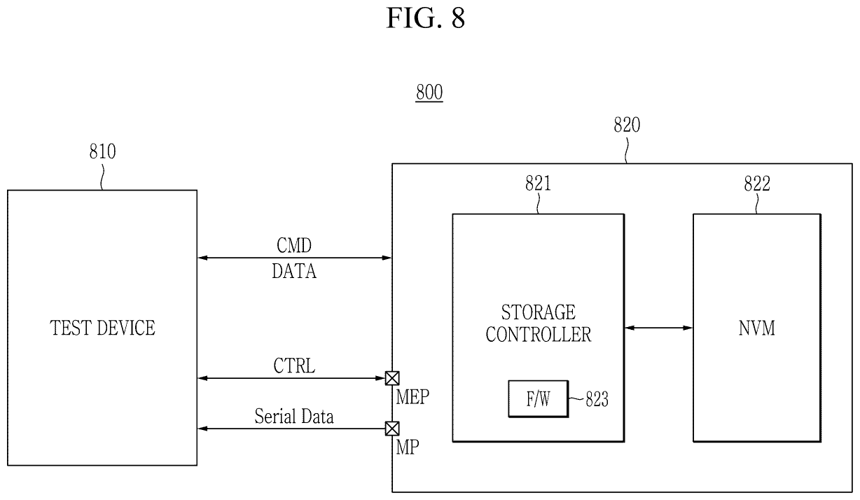

FIG. 8 is a block diagram showing a test system according to an embodiment.

Referring to FIG. 8, the test system 800 may include a test device 810 and a storage device 820. The test device 810 may control the overall operation of the test system 800. For example, the test device 810 may store data DATA in the storage device 820 or read data DATA stored in the storage device 820. The test device 810 may transmit a command signal CMD related to the operation of the storage device 820, such as a read command and a write command. The storage device 820 may transmit the data signal DATA according to the read command to the test device 810. The storage device 820 may store the DATA received from the test device 810 according to the write command received from the test device 810.

As an example of an interface for the communication between the test device 810 and the storage device 820, various interface types such as universal flash storage (UFS), advanced technology attachment (ATA), serial ATA (SATA), external SATA (e-SATA), small computer small interface (SCSI), serial attached SCSI (SAS), peripheral component interconnection (PCI), PCI express (PCI-E), IEEE 1394, universal serial bus (USB), secure digital (SD) card, multimedia card (MMC), embedded multimedia card (eMMC), compact flash (CF) card interface, etc. may be applied. In some embodiments, the test device 810 may communicate with the storage device 820 according to one of various standards.

In some embodiments, the test device 810 may receive the serial data Serial Data generated by a serializer (e.g., see 391 or 401) in the storage device 820. The serializer may serialize the data signal DATA and output the serial data signal Serial Data to the second connection terminal MP.

Whereas the serial data signal Serial Data is transmitted sequentially one bit at a time, since the data signal DATA is transmitted by multiple bits simultaneously, the data transfer rate of the serial data signal Serial Data may be lower than the data transfer rate of the data signal DATA. If the data transfer rate is low, the time to transmit each bit increases, and the eye margin may increase. Accordingly, the eye margin of the serial data signal Serial Data may be larger than the eye margin of the data signal DATA.

In some embodiments, the storage device 820 may receive the monitoring enable control signal CTRL from the test device 810 through the first connection terminal MEP. The storage device 820 may receive the monitoring enable control signal CTRL to initiate the operation of the serializer. Also, the storage device 820 may transmit the serial data Serial Data generated based on the serializer to the test device 810 through the second connection terminal MP.

The storage device 820 may include a storage controller 821 (e.g., a controller circuit) and a non-volatile memory device 822. The storage controller 821 may control the overall operation of the storage device 820. The storage controller 821 may receive a read request or a program request from the test device 810. The non-volatile memory device 822 may be a storage medium configured to store the data signal DATA or output the stored data signal DATA according to a request from the storage controller 821.

The storage controller 821 may include firmware 823. The firmware 823 may include low-level software to provide an interface between the hardware of the storage device 820 and an operating system and the software of at an application program level.

In some embodiments, the firmware 823 may include the power status information and the gear speed information of the storage device 820. The storage controller 821 may perform basic operations of the storage device 820 based on the firmware 823. Even if the storage device 820 is initialized, the firmware 823 may remain in an executable state.

A program executing on the firmware 823 may receive the command signal CMD and the address signal ADDR from the test device 810. The program of the firmware 823 may change the power status information and the gear speed information of the storage device 820 based on the command signal CMD and the address signal ADDR. The program of the firmware 823 may transmit the power status information and the gear speed information of the storage device 820 to the non-volatile memory device 822 based on the monitoring enable control signal. For example, the program may load the power status information and/or the gear speed information from storage of the firmware 823 to change the power status information and/or the gear speed information of the storage device 820.

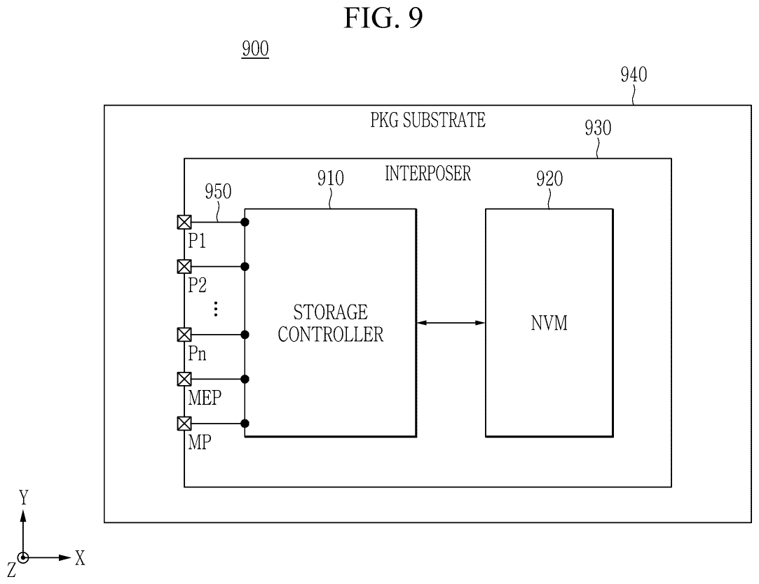

FIG. 9 is a cross-sectional view of a storage device according to an embodiment.

Referring to FIG. 9, the storage device 900 may include a storage controller 910, a non-volatile memory device 920, an interposer 930 mounting the non-volatile memory device 920, and a printed circuit board (PCB) 940. The storage controller 910, the non-volatile memory device 920, the interposer 930, and the printed circuit board (PCB) 940 may be arranged to overlap a plane having the X-axis and the Y-axis. The interposer 930 may be positioned on the printed circuit board (PCB) 940 with the Z axis as a reference, and the storage controller 910 and the non-volatile memory device 920 may be positioned on the interposer 930.

A plurality of connection terminals P1, P2, . . . , Pn, the first connection terminal MEP, and the second connection terminal MP may be connected to the storage controller 910 through a wiring 950. In this case, the plurality of connection terminals P1, P2, . . . , Pn, the first connection terminal MEP, and the second connection terminal MP may be positioned on the interposer 930.

The test device (810 in FIG. 8) may transmit a signal according to the communication interface standard with the storage device 820 through the plurality of connection terminals P1, P2, . . . , Pn.

The test device 810 may transmit the monitoring enable control signal CTRL to the storage device 900 through the first connection terminal MEP. The test device 810 may detect the serial data signal Serial Data that the storage device 900 transmits to the test device 810 by probing the second connection terminal MP.

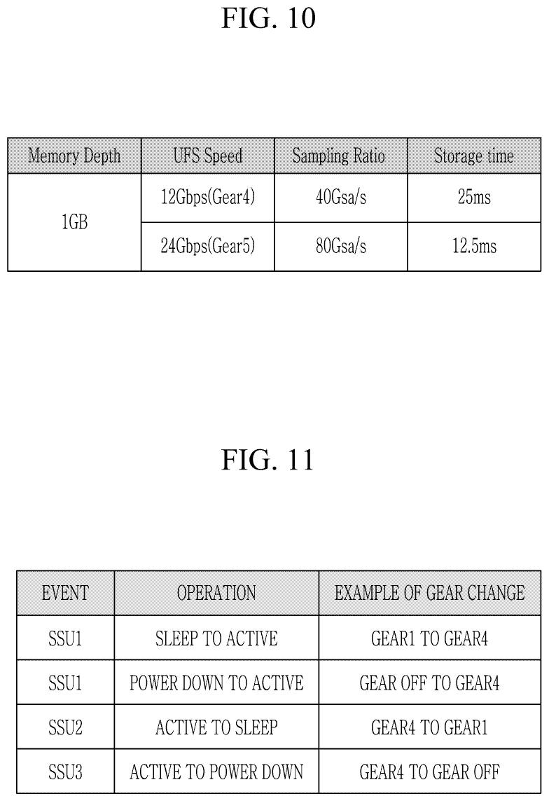

FIG. 10 is an example diagram of a data sampling ratio and a data storage time according to a capacity of a non-volatile memory device.

Assuming that the storage device (820 in FIG. 8) is a device that follows a UFS standard, a UFS speed may refer to the speed of transmitting data from the test device (810 in FIG. 8) to the storage device 820. Proportional to a UFS speed, the UFS speed may be referred to as a gear1, a gear2, a gear3, a gear4, and a gear5. As UFS speed increases, data transmitted from the storage controller (821 in FIG. 8) to the non-volatile memory device 822 needs to be sampled more quickly, leading to an increased data sampling rate. For example, the data sampling ratio of the gear 5 may be faster than the data sampling ratio of the gear 4.

The test device 810 may receive the data stored in the non-volatile memory device 822, and the integrity of the data signal may be verified when the data signal received by the test device 810 matches the data stored in the non-volatile memory device 822. In an embodiment, the storage time of the non-volatile memory device 822 is 250 ms or more to verify the integrity of the data signal by comparing the data signal received from the test device 810 and the data stored in the non-volatile memory device 822.

The storage time of the non-volatile memory device 822 may be calculated by dividing the data sampling ratio by the memory depth of the non-volatile memory device 822.

If the storage time of the non-volatile memory device 822 is less than 250 ms, the data stored in the non-volatile memory device 822 may be removed before the test device 810 receives the data signal. In this case, the data signal received from the test device 810 cannot be compared with the data stored in the non-volatile memory device 822, so the test device 810 may not be able to verify the integrity of the data signal.

Referring to FIG. 10, the memory depth of the non-volatile memory device (822 in FIG. 8) is 1 GB, the UFS speed that transmits data from the test device (810 in FIG. 8) to the storage device (820 in FIG. 8) is 12 Gbs (Gear4), and the sampling ratio of the data from non-volatile memory device 822 is 40 Gsa/s, the storage time of the non-volatile memory device 822 is only 25 ms.

Likewise, if the memory depth of the non-volatile memory device 822 is 1 GB, the UFS speed that transmits the data from the test device 810 to the storage device 820 is 24 Gbs (Gear5), and the data sampling ratio (Sampling Ratio) is 80 Gsa/s in the non-volatile memory device 822, the storage time of the non-volatile memory device 822 is only 12.5 ms.

Accordingly, if the data sampling ratio of the non-volatile memory device 822 increases, the data storage time becomes short, and the test device 810 may not be able to verify the integrity of the data signal.

FIG. 11 is an example diagram showing a power status information and a gear speed information that are changed when a storage device receives a command from a test device.

The storage device (820 in FIG. 8) may receive a SSU1 command, a SSU2 command, and a SSU3 command from the test device (810 in FIG. 8). When the storage device 820 receives the SSU1 command, the status information of the storage device 820 may change from a disabled state (e.g., SLEEP) to an enable state (e.g., ACTIVE). At this time, the gear speed information of the storage device 820 may be changed from the gear 1 GEAR1 to the gear 4 GEAR4. When the storage device 820 receives the SSU1 command, the storage device 820 may change the operation from a power-off state (e.g., POWER DOWN) to an enable state (e.g., ACTIVE). At this time, the gear speed information of the storage device 820 may be changed from a gear off GEAR OFF to a gear 4 GEAR4.

When the storage device 820 receives the SSU2 command, the status information of the storage device 820 may change from the enable state to the disable state. At this time, the gear speed information of the storage device 820 may be changed from the gear 4 GEAR 4 to the gear 1 GEAR1.

When the storage device 820 receives the SSU3 command, the status information of the storage device 820 may change from the enable state to the power off state. At this time, the gear speed information of the storage device 820 may be changed from the gear 4 GEAR 4 to the gear off GEAR OFF.

If the UFS speed is high, the gear speed of the storage device 820 may be increased to quickly receive the command signal transmitted by the test device 810. At this time, at the speed of the gear4 Gear4 or the gear5 Gear5, the storage device 820 may not receive the command signal from the test device 810. Alternatively, even if the storage device 820 receives the command signal from the test device 810, it may not be able to capture the command signal.

For example, if the storage device 820 operates at the gear 4 GEAR 4 and the UFS speed is higher than the UFS speed of the gear 2 GEAR 2 and the gear 3 GEAR 3, the storage device 820 may not be able to receive the command from the test device 810. In addition, to change the gear of the storage device 820 from the gear 4 GEAR 4 to the gear 1 GEAR 1, the SSU1 command needs to be received from the test device 810. However, because the UFS speed is too fast, the storage device 820 may not be able to capture the SSU1 command signal.

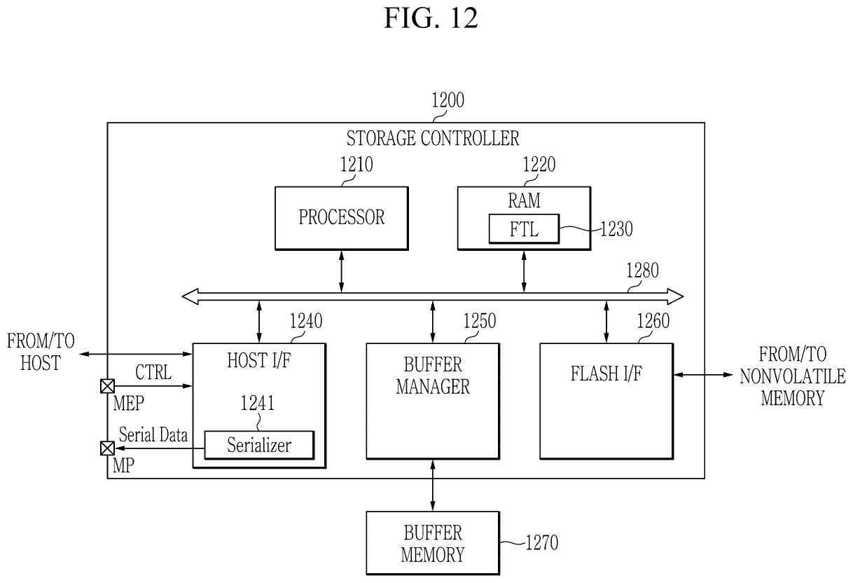

FIG. 12 is a block diagram of a storage controller according to an embodiment. The storage controller 910 may be implemented by the storage controller of FIG. 12.

Referring to FIG. 12, a storage controller 1200 may access the non-volatile memory device (822 in FIG. 8) and a buffer memory 1270. The storage controller 1200 may perform a writing, a reading, and an erasing according to the request of the test device (810 in FIG. 8). The storage controller 1200 may write the data requested to be written to the non-volatile memory device 822 and may read and output the data requested to be read from the non-volatile memory device 822.

The storage controller 1200 may manage the non-volatile memory device 822 by using the buffer memory 1270. For example, the storage controller 1200 may temporarily store data intended for writing in the non-volatile memory device 822 or data read from the non-volatile memory device 822 in the buffer memory 1270.

The storage controller 1200 may include a processor 1210, a random access memory (RAM) 1220, a host interface circuit 1240, a buffer manager 1250 (e.g., a logic circuit), and a flash interface circuit 1260.

The processor 1210 may control the overall operations of the storage controller 1200 and perform logical operations. The processor 1210 may communicate with the test device 810 through the host interface circuit 1240, with the non-volatile memory device 822 through the flash interface circuit 1260, and with the buffer memory 1270 through the buffer manager 1250. The processor 1210 may control the non-volatile memory device 822 by using the RAM 1220 as an operation memory, a cache memory, or a buffer memory.

The RAM 1220 may be used as the operation memory, the cache memory, or the buffer memory of the processor 1210. The RAM 1220 may store codes and commands executed by the processor 1210. The RAM 1220 may store the data processed by the processor 1210. The RAM 1220 may, for example, be implemented as a Static RAM (SRAM). Particularly, the RAM 1220 may store a Flash Translation Layer (FTL) 1230. The FTL 1230 may perform address mapping, garbage collection, wear leveling, etc. for interfacing between the non-volatile memory device 822 and the test device 810.

The host interface circuit 1240 is configured to communicate with an external test device 810. The host interface circuit 1240 may be configured to communicate using at least one of the various communication methods described previously with respect to FIG. 8.

The host interface circuit 1240 may receive the command signal CMD, the data signal DATA, and the monitoring enable control signal CTRL from the test device 810. The command signal CMD signal may include the SSU1 command, the SSU2 command, or the SSU3 command. The state of the storage device (820 in FIG. 8) may be changed based on whether the command CMD is received from the host interface circuit 1240.

For example, when the host interface circuit 1240 receives the SSU1 command signal CMD from the test device 810, the power state of the storage device 820 may be changed to the enable state. In the enable state, the host interface circuit 1240 may enter an idle state to receive the command CMD. When the host interface circuit 1240 receives the SSU2 command signal CMD from the test device 810, the power state of the storage device 820 may be changed to a disable state. Additionally, when the host interface circuit 1240 receives the SSU3 command signal CMD from the test device 810, the power state of the storage device 820 may be changed to the power off state.

In some embodiments, the host interface circuit 1240 may receive the monitoring enable control signal CTRL from the test device 810 through the first connection terminal MEP. The storage device 820 may receive the monitoring enable control signal CTRL to initiate the operation of the serializer 1241. The host interface circuit 1240 includes a serializer 1241 and may transmit the serial data Serial Data generated by the serializer 1241 to the test device 810.

Specifically, the host interface circuit 1240 may receive the data signal DATA received by a flash interface circuit 1260 from the non-volatile memory device 822 through a bus 1280. The serializer 1241 may serialize a data signal DATA to generate the serial data Serial Data and output the serial data Serial Data to the second connection terminal MP.

The buffer manager 1250 is configured to control the buffer memory 1270 according to the control of the processor 1210. The buffer manager 1250 controls the buffer memory 1270 to temporarily store the data exchanged between the non-volatile memory device 822 and the test device 810. The buffer memory 1270 may store commands and data that are executed and processed by the storage controller 1200. The buffer memory 1270 may temporarily store data stored in or to be stored in the non-volatile memory device 822.

The buffer memory 1270 may be implemented as a volatile memory such as Dynamic Random Access Memory (DRAM), Static RAM (SRAM), etc. However, it is not limited to this, and the buffer memory 1270 may be implemented with a resistive non-volatile memory such as a magnetic RAM (MRAM), a phase change RAM (PRAM), or a resistive RAM (ReRAM), and various types of the non-volatile memory, such as a flash memory, a Nano Floating Gate Memory (NFGM), a Polymer Random Access Memory (PoRAM), or a Ferroelectric Random Access Memory (FRAM). In the present embodiment, the buffer memory 1270 is shown as being provided outside the storage controller 1200, but is not limited to this. For example, the buffer memory 1270 may be provided inside the storage controller 1200.

The flash interface circuit 1260 is configured to communicate with the non-volatile memory device 822 under the control of the processor 1210. The flash interface circuit 1260 may communicate with the non-volatile memory device 822 through a plurality of channels. Specifically, the flash interface circuit 1260 may transmit/receive commands, addresses, and data with the non-volatile memory device 822 through the plurality of channels.

The non-volatile memory device 822 may perform a write operation, a read operation, and an erase operation under the control of the storage controller 1200. The non-volatile memory device 822 may receive a write command, an address, and data from the storage controller 1200, and write data to the storage space identified by the address. The non-volatile memory device 822 may receive a read command and an address from the storage controller 1200, read data from the storage space identified by the address, and output the read data to the storage controller 1200. The non-volatile memory device 822 may receive an erase command and an address from the storage controller 1200 and erase data in the storage space identified by the address.

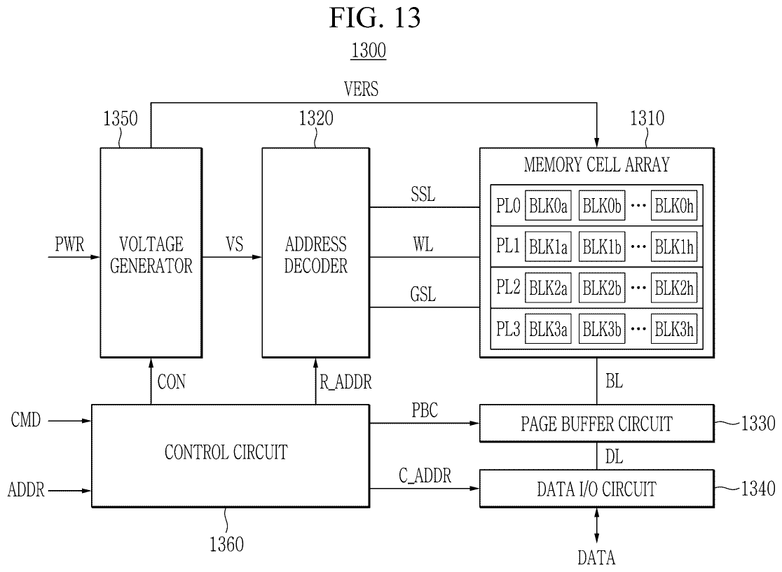

FIG. 13 is a block diagram showing an example of a non-volatile memory device included in a storage device according to an embodiment. For example, the non-volatile memory device 920 of FIG. 9 may be implemented by the non-volatile memory device of FIG. 13.

Referring to FIG. 13, a non-volatile memory device 1300 includes a memory cell array 1310, an address decoder 1320, a page buffer circuit 1330, a data input/output circuit 1340, a voltage generator 1350, and a control circuit 1360.

The memory cell array 1310 is connected to the address decoder 1320 through a plurality of string selection lines SSL, a plurality of word lines WL, and a plurality of ground selection lines GSL.

Additionally, the memory cell array 1310 is connected to the page buffer circuit 1330 through the plurality of bit lines BL. The memory cell array 1310 may include a plurality of memory cells connected to the plurality of word lines WL and the plurality of bit lines BL. The memory cell array 1310 may be divided into a plurality of planes PL0 to PL3 each including memory cells. Each of the plurality of planes PL0 to PL3 may include a plurality of memory blocks BLK0a, BLK0b, . . . , BLK0h, BLK1a, BLK1b, . . . , BLK1h, BLK2a, BLK2b, . . . , BLK2h, BLK3a, BLK3b, . . . , BLK3h. In some embodiments, the plurality of memory blocks e.g., BLK0a, BLK0b, . . . , BLK0h included in the same plane (e.g., PL0) may share the same bit line. Also, the plurality of memory blocks BLK0a, BLK0b, . . . , BLK0h, BLK1a, BLK1b, . . . , BLK1h, BLK2a, BLK2b, . . . , BLK2h, BLK3a, BLK3b, . . . , BLK3h may be respectively divided into a plurality of pages. According to an embodiment, the memory cell array 1310 may be formed in a 2-dimensional array structure or a 3-dimensional vertical array structure.

The control circuit 1360 may receive the command signal CMD and the address signal ADDR and control the erase loop, program loop, and the read operations of the non-volatile memory device 1300 based on the command signal CMD and the address signal ADDR.

The control circuit 1360 may generate control signals CON for controlling the voltage generator 1350 and control signals PBC for controlling the page buffer circuit 1330 based on the command CMD. The control circuit 1360 may generate a row address R_ADDR and a column address C_ADDR based on an address ADDR. The control circuit 1360 may provide the row address R_ADDR to the address decoder 1320 and the column address C_ADDR to the data input/output circuit 1340.

The address decoder 1320 is connected to the memory cell array 1310 through the plurality of string selection lines SSL, the plurality of word lines WL, and the plurality of ground selection lines GSL.

For example, during the erase/program/read operations, in response to the row address R_ADDR, the address decoder 1320 may determine at least one of the plurality of word lines WL as a selected word line, and determine the remaining word lines except the selected word line among the plurality of word lines WL as non-selected word lines.

Additionally, during the erase/program/read operations, the address decoder 1320, in response to the row address R_ADDR, may determine at least one of the plurality of string selection lines SSL as a selected string selection line, and the remaining string selection lines as non-selected string selection lines.

Additionally, during the erase/program/read operations, the address decoder 1320, in response to the row address R_ADDR, may determine at least one of the plurality of ground selection lines GSL as a selected ground selection line, and the remaining ground selection lines as non-selected ground selection lines.

The voltage generator 1350 may generate voltages VS for the operation of the non-volatile memory device 1300 based on the power voltage PWR and the control signals CON. The voltages VS may be applied to the plurality of string selection lines SSL, the plurality of word lines WL, and the plurality of ground selection lines GSL through the address decoder 1320.

The page buffer circuit 1330 may be connected to the memory cell array 1310 through the plurality of bit lines BL. The page buffer circuit 1330 may include a plurality of page buffers.

The page buffer circuit 1330 may store write data to be programmed in the memory cell array 1310 or a read data detected from the memory cell array 1310. In other words, the page buffer circuit 1330 may operate as a write driver or a detection amplifier depending on the operation mode of the non-volatile memory device 1300.

The data input/output circuit 1340 may be connected to the page buffer circuit 1330 through data lines DL. The data input/output circuit 1340, in response to the column address C_ADDR, may provide the write data DATA received from outside (e.g., the test device 810 and/or the storage controller 821 in FIG. 8) to the memory cell array 1310 through the page buffer circuit 1330.

The data input/output circuit 1340 may provide the data signal DATA output from the memory cell array 1310 through the page buffer circuit 1330 to the storage controller 821.

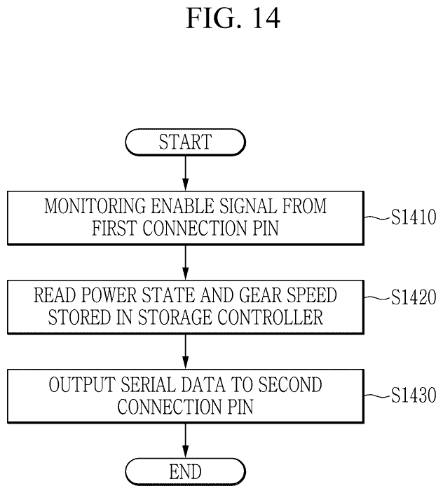

FIG. 14 is a flowchart showing a process of outputting serial data through a second connection terminal according to an embodiment.

In a step (S1410), the storage device (820 in FIG. 8) may receive a monitoring enable signal from the test device (810 in FIG. 8) through a first connection terminal MEP. The monitoring enable signal may be transmitted to the storage controller (821 in FIG. 8) and the serializer (1241 in FIG. 12).

In a step (S1420), the storage device 820 may read data stored in the storage controller 821 in response to the monitoring enable signal. A power status information Power Status and a gear speed information Gear Speed stored in the firmware (823 in FIG. 8) may be read based on the monitoring enable signal. At this time, the storage device 820 may receive the address signal ADDR and the command signal CMD from the test device 810 and read the information (e.g., a power state or status and a gear speed) stored in the firmware 823 based thereon.

In a step (S1430), the storage device 820 may output the serial data signal Serial Data to the test device 810 through the second connection terminal MP. The storage device 820 may convert the power status information Power Status and the gear speed information Gear Speed into the serial data Serial Data. The serializer 1241 may generate the serial data Serial Data by converting the power status information Power Status and the gear speed information Gear Speed received from the firmware 823 into data having a serial format.

Specifically, the serializer 1241 may generate the serial data Serial Data by converting the information stored in parallel in the firmware 823 to data of a serial format. When the information amount of the serial data Serial Data is less than the information amount stored in the firmware 823, the data transfer rate of the serial data Serial Data may be lower than the data transfer rate of the information stored in the firmware 823.

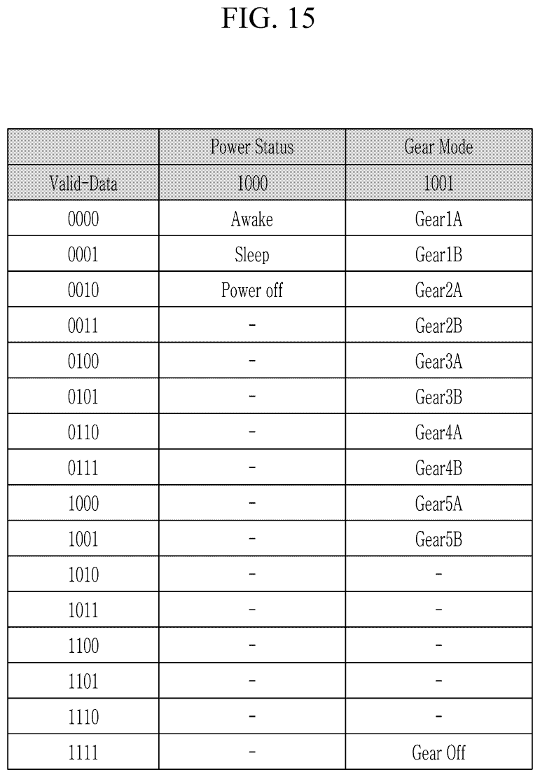

FIG. 15 is an example diagram of power status information and gear speed information stored in a firmware.

Referring to FIG. 15, in the firmware (823 of FIG. 8), the power status information Power Status of the storage device (820 in FIG. 8) may be stored as 4 bit data (‘1000’), and the gear speed information Gear Speed of the storage device 820 may be stored as 4 bit data (‘1001’). The power status information Power Status may indicate one of the enabled state, the disabled state, and the power off state, and the gear speed information Gear Speed may indicate one of a gear 1A, a gear 1B (Gear 1B), a gear 2A, a gear 2B (Gear 2B), a gear 3A (Gear 3A), a gear 3B (Gear 3B), a gear 4A (Gear 4A), a gear 4B (Gear 4B), a gear 5A (Gear 5A), a gear 5B (Gear 5B), and a gear off (Gear Off). The higher the number of the gears, the higher the UFS speed may be. For example, the gear 4A may mean the UFS speed of 12 Gbps, and the gear 5A may mean the UFS speed of 242 Gbps.

When the storage device 820 receives the SSU1 command from the test device (810 in FIG. 8), the storage device 820 may enter the enable state. At this time, 4 bit data (‘0000’) may be stored in the firmware 823. When the storage device 820 receives the SSU2 command from test device 810, the storage device 820 may enter the disable state. At this time, 4 bit data (‘0001’) may be stored in firmware 823. When the storage device 820 receives the SSU3 command from the test device, the storage device 820 may enter the power-off state. At this time, 4 bit data (‘0010’) may be stored in the firmware 823.

The gear speed information Gear Speed may be changed based on the change of the power status information Power Status. For example, when the storage device 820 receives the SSU1 command, the power status information Power Status of the storage device 820 may change from the disable state to the enable state. At this time, the gear speed information Gear Speed of the storage device 820 changes from the gear 1 Gear 1 to the gear 4A Gear 4A, and 4 bit data (‘0110’) corresponding to the gear 4A Gear 4A may be stored in the firmware 823. It can be saved.

When the storage device 820 receives the SSU2 command from the test device 810, the power status information Power Status of the storage device 820 may change from the enable state to the disable state. At this time, the gear speed information Gear Speed of the storage device 820 is changed from the gear 4A to the gear 1A, and 4 bit data (‘0000’) corresponding to the gear 1A may be stored in firmware 823.

When the storage device 820 receives the SSU3 command from the test device 810, the power status information Power Status of the storage device 820 may change from the enable state to the power off state. At this time, the gear speed information Gear Speed of the storage device 820 changes from the Gear 4A to the Gear Off, and 4 bit data (‘1111’) corresponding to the Gear Off may be stored in the firmware 823.

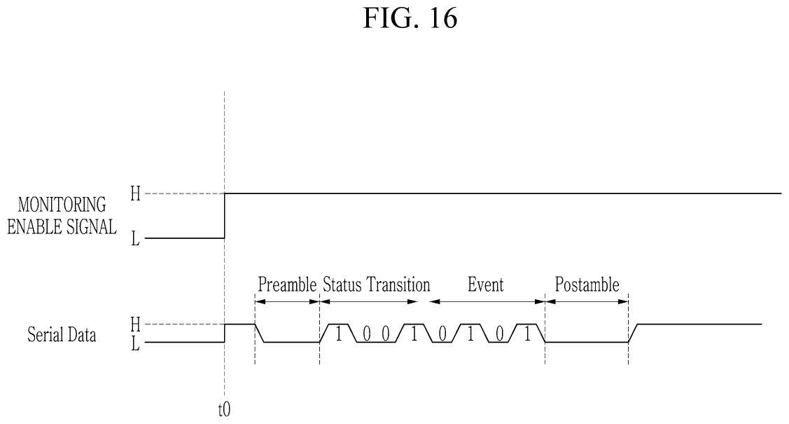

FIG. 16 is an example of serial data being output based on a monitoring enable signal.

Referring to FIG. 16, the storage device (820 of FIG. 8) may receive a monitoring enable signal of logic high level H at time t0, and may receive the command signal CMD reading the power status information Power Status and the gear speed information Gear Speed stored in the firmware (823 of FIG. 8). The storage device 820 may read the information stored in the firmware 823 after time t0 and serialize the read information to output the serial data signal Serial Data.

The serial data Serial Data may include the power status information Power Status and the gear speed information Gear Speed. In addition, the serial data Serial data may be output through a section Preamble that outputs the preamble, a section Status transition that outputs status change information, a section Event that outputs an event, and a section Postamble that outputs the postamble.

The storage device 820 may transmit the status change information and the event in the section Status transition that outputs the status change information of the storage device 820 and the section (Event) that outputs the event between the preamble section Preamble and the postamble section Postamble. Specifically, when the monitoring enable control signal CTRL transitions from a disable level L to an enable level H, the host interface circuit (1240 in FIG. 12) may output the information for selecting one of the power status information Power Status and the gear speed information Gear Speed and the data representing the value of the power status information Power Status or the gear speed information Gear Speed as the serial data Serial Ddata. In addition, when the monitoring enable control signal CTRL transitions from the disable level L to the enable level H, the host interface circuit 1240 may output the preamble before outputting the serial data Serial Data, and the postamble after outputting the serial data Serial Data.

During the preamble section Preamble, the storage device 820 may perform a timing synchronization with the test device 810, so that the start of the data transmission may be clearly recognized. During the postamble section Postamble, the storage device 820 may clearly recognize the end of the power status information Power Status and the gear speed information Gear Speed, so the accuracy of the data processing may be increased.

The storage device 820 may transmit the information for selecting either power status information Power Status or the gear speed information Gear Speed of the storage device 820 to the test device 810 during the status change section Status transition. Additionally, the storage device 820 may transmit the data indicating the value of the power status information Power Status or the gear speed information Gear Speed of the storage device 820 to the test device 810 during the event section Event.

For example, the storage device 820 may transmit 4-bit data (‘1001’), which is a signal for selecting the gear speed information Gear Speed, to the test device 810 during the status change section Status transition. The 4-bit data (‘1001’) transmitted to the test device 810 during the status change section Status transition may mean selecting the gear speed information Gear Speed among the power status information Power Status and the gear speed information Gear Speed of the storage device 820.

The storage device 820 may transmit 4 bit data (‘0101’) to the test device 810 during the event section Event. The 4-bit data (‘0101’) transmitted to the test device 810 during the event section Event may mean the gear speed information of the gear 3B. For example, as shown in FIG. 15, the first column of the sixth row is (‘0101’) corresponding to Gear3B.

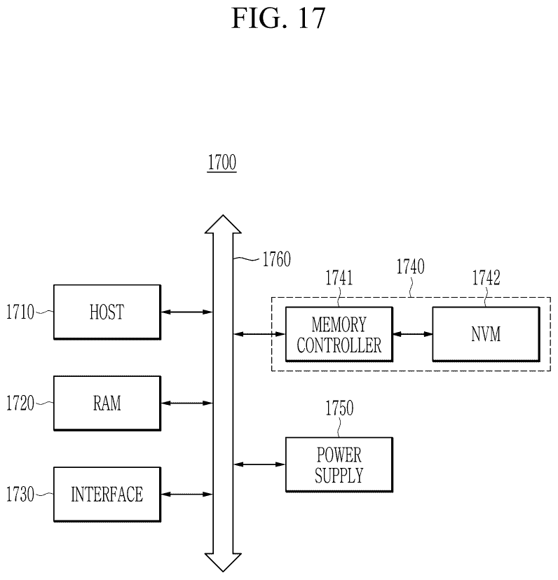

FIG. 17 is a block diagram showing a computing system including a non-volatile memory device according to an embodiment.

Referring to FIG. 17, a computer system 1700 may include a processor 1710, a RAM 1720, an interface device 1730, a memory system 1740, a power supply 1750, and a bus 1760.

The processor 1710, the RAM 1720, the interface device 1730, the memory system 1740, and the power supply 1750 may be communicate with each other through the bus 1760. The bus 1760 corresponds to a path through which data is transmitted.

The processor 1710 may include at least one of a microprocessor, a digital signal processor, a micro controller, and logic devices capable of performing similar functions thereto.

The RAM 1720 may be used as a working memory to increase the performance of the processor 1710. The interface device 1730 may perform a function of transmitting data to a communication network or receiving data from a communication network.

The interface device 1730 may be wired or wireless. For example, the interface device 1730 may include an antenna or a wireless transceiver.

The memory system 1740 may store data and/or commands, etc. The memory system 1740 may include a memory controller 1741 and a non-volatile memory device 1742.

The memory controller 1741 may receive commands, addresses, data, and monitoring enable signals from the processor 1710. The memory controller 1741 may convert the address signal received from the host device into an address signal indicating the memory address of the non-volatile memory device 1742. The memory controller 1741 may transmit the converted address and the read command signal to the non-volatile memory device 1742.

The non-volatile memory device 1742 may transmit the data stored in the address of the cell corresponding to the converted address to the memory controller 1741. Firmware included in the memory controller 1741 may store the data received from the non-volatile memory device 1742.

The power supply 1750 may supply an operating power to the processor 1710, the RAM 1720, the interface device 1730, and the memory system 1740.

The computing system 1700 may be applied to any electronic product that can transmit and/or receive information in a wireless environment such as a personal digital assistant (PDA) portable computer, a web tablet, a wireless phone, a mobile phone, a digital music player, a memory card, etc.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A memory device comprising:
a plurality of mode registers storing a plurality of status codes;
a data input/output circuit configured to receive one status code of the plurality of status codes from one of the plurality of mode registers, sample the one status code to generate sampled data and output the sampled data; and
a serializer configured to receive the sampled data from the data input/output circuit, convert the sampled data into serial data, and output the serial data through a first connection terminal that is separate from a data connection terminal configured to exchange access data.

2. The memory device of claim 1, further comprising:
a clock control circuit configured to generate an internal clock signal and a data clock signal whose frequency is different from the internal clock signal based on a monitoring enable control signal received from an external test device,
the data input/output circuit is further configured to sample the one status code in synchronization with the data clock signal, and
the serializer is further configured to output the serial data in synchronization with the internal clock signal.

3. The memory device of claim 2, further comprising:
a control logic circuit configured to initiate operation of the serializer based on the monitoring enable control signal and control the clock control circuit to generate the internal clock signal.

4. The memory device of claim 3, wherein:
the control logic circuit is further configured to receive a mode register read command signal from the test device and issue a command that causes the one status code stored in the mode register to be transmitted to the data input/output circuit.

5. The memory device of claim 4, wherein:
the control logic circuit is further configured to receive a test entry mode command signal as the monitoring enable control signal from the test device and initiate the operation of the serializer based on the test entry mode command signal.

6. The memory device of claim 2, wherein:
when the monitoring enable control signal transitions from a disable level to an enable level, the serializer is further configured to output a mode register address code and the one status code corresponding to one mode register among the plurality of mode registers as the serial data.

7. The memory device of claim 6, wherein:
when the monitoring enable control signal transitions from the disable level to the enable level, the serializer is further configured to output a preamble before outputting the serial data and output a postamble after outputting the serial data.

8. The memory device of claim 6, further comprising:
a memory cell array including a plurality of memory banks,
the one status code includes one of a power status information, gear speed information, and Post Package Repair (PPR) information corresponding to each of the plurality of memory banks.

9. The memory device of claim 2, wherein:
the monitoring enable control signal is received through a second connection terminal that is separate from the first connection terminal and the data connection terminal, and is transmitted to the serializer and the clock control circuit.

10. The memory device of claim 9, further comprising:
an interposer including the first connection terminal and the second connection terminal, and
a semiconductor chip positioned on the interposer and including the plurality of mode registers, the data input/output circuit, and the serializer.

11. A storage device comprising:
a storage controller configured to receive a monitoring enable control signal through a first connection terminal separate from a data connection terminal configured to exchange access data, serialize power status information of the storage device and gear speed information of the storage device based on the monitoring enable control signal to generate serial data, and output the serial data through a second connection terminal separate from the first connection terminal and the data connection terminal; and
a non-volatile memory device configured to perform access operations based on the access data under control from the storage controller.

12. The storage device of claim 11, wherein the storage controller comprises:
firmware storing the power status information and the gear speed information;
a host interface circuit configured to receive the monitoring enable control signal and receive a command signal to read the power status information and the gear speed information from the firmware; and
a flash interface circuit configured to communicate with the non-volatile memory device through a plurality of channels.

13. The storage device of claim 12, wherein the firmware is configured to change the power status information and the gear speed information based on a command signal and address signal received from a test device, and transmit the changed power status information and gear speed information to the non-volatile memory device based on the monitoring enable control signal.

14. The storage device of claim 12, wherein the host interface circuit includes a serializer configured to generate serial data by serializing the power status information and the gear speed information in response to the monitoring enable control signal.

15. The storage device of claim 12, wherein the host interface circuit is further configured to output information for selecting one of the power status information and the gear speed information and data indicating a value of the power status information or the gear speed information as the serial data when the monitoring enable control signal transitions from a disable level to an enable level.

16. The storage device of claim 15, wherein the host interface circuit is further configured to output a preamble before outputting the serial data, and output a postamble after outputting the serial data when the monitoring enable control signal transitions from the disable level to the enable level.

17. The storage device of claim 11, further comprising:
an interposer including the first connection terminal, and the second connection terminal, and
a semiconductor chip positioned on the interposer and including the storage controller and the non-volatile memory device.

18. A test method of memory device comprising:
reading a status code stored in one mode register among a plurality of mode registers;
receiving a monitoring enable control signal through a first connection terminal separate from data connection terminal configured to exchange access data;
converting the status code into serial data based on the monitoring enable control signal; and
outputting the serial data through a second connection terminal separate from the first connection terminal and the data connection terminal.

19. The test method of the memory device of claim 18, wherein converting the status code into the serial data comprises:
generating an internal clock signal based on the monitoring enable control signal; and
converting the status code in synchronization with the internal clock signal for generating the serial data.

20. The test method of the memory device of claim 18, wherein outputting the serial data through the second connection terminal comprises:
outputting a preamble before outputting the serial data;
outputting a mode register address code corresponding to one mode register among the plurality of mode registers;
outputting one of power status information, gear speed information, and Post Package Repair (PPR) information corresponding to each of a plurality of memory banks included in a memory cell array of the memory device as the one status code; and
outputting a postamble after outputting the serial data.
